(19) United States
(12) Patent Application Publication
(10) Pub. No.: US 2024/0154576 A1
(43) Pub. Date: May 9, 2024

(54) LOW NOISE AMPLIFIER

(71) Applicant: X-FAB France SAS, Corbeil-Essones (FR)

(72) Inventors: Ousmane SOW, Corbeil-Essonnes (FR); Imène LAHBIB, Corbeil-Essonnes (FR); Gregory U’REN, Corbeil-Essonnes (FR)

(21) Appl. No.: 18/387,936

(22) Filed: Nov. 8, 2023

(30) Foreign Application Priority Data
Nov. 8, 2022 (FR) 2211641
Feb. 1, 2023 (GB) 2301416.0

(51) Int. Cl. H03F 1/22; H03F 3/195

(52) U.S. Cl. CPC H03F 1/22; H03F 3/195; H03F 2200/294; H03F 2200/451

(57) ABSTRACT

A low noise amplifier, LNA, including a silicon on insulator, SOI, substrate having a buried oxide, BOX, layer, wherein the SOI substrate includes a bulk region within which the buried oxide layer is removed. The SOI substrate is a high resistance, HR, SOI substrate including a silicon handle wafer having a resistivity greater than 3 kΩ-cm. The low noise amplifier, LNA, further has a bipolar transistor located in the bulk region, and a thick metal layer for connecting to the LNA.

This application claims priority to French Patent Application No. 2211641 filed on Nov. 8, 2022, and United Kingdom Application No. 2301416.0 filed on Feb. 1, 2023. The entire contents of both of these applications is hereby incorporated by reference.

The present disclosure concerns low noise amplifiers (LNAs).

### BACKGROUND

New telecommunications technology requires new and improved devices on the semiconductor level. The new standard, 5G-NR can enable higher data rates (>100 Mbit/s, max of 20 Gbit/s), higher density (more connected equipment/km2), and lower latency (ideally from 10 to 1 ms).

For 5G, group III-V semiconductor technologies (e.g. GaAs) look promising, but have some downsides such as high power consumption, low quality factor passives, low integration level, difficulty to mass produce and high costs.

In silicon on insulator (SOI) technology circuitry is formed in a silicon layer that is isolated from the substrate by an electrically insulating layer. This has the advantage of reduced in parasitic capacitance which allows access to a more desirable power-speed performance horizon. Hence, SOI structures can be advantageous for high frequency applications such as radio frequency (RF) communication circuits.

### SUMMARY

Aspects of the disclosure provide a low noise amplifier (LNA) and a user equipment (UE) comprising such an LNA as set out in the appended claims.

Certain embodiments are described below with reference to the accompanying drawings.

### BRIEF DESCRIPTION OF DRAWINGS

FIG. 1 depicts a schematic diagram of a part of a telecommunications system, such as a UE, according to an embodiment;

FIG. 2 depicts a circuit diagram of an LNA comprising a cascode structure with two bipolar transistors on a SOI substrate;

FIG. 3 depicts a circuit diagram of an LNA comprising a hybrid cascode structure with a bipolar transistor as common emitter and a SOI transistor as common gate;

FIG. 4 depicts a circuit diagram of an LNA with two amplifying stages, wherein the first stage comprises a single common emitter bipolar transistor and the second stage comprises a hybrid cascode structure;

FIG. 5a depicts a schematic cross-section of a part of a LNA illustrating a bipolar transistor in a bulk region within which the BOX layer is removed from the SOI substrate;

FIG. 5b depicts a schematic diagram of a part of a LNA illustrating the SOI substrate and the backend stack comprising metal layers on the substrate;

FIG. 6 depicts a circuit diagram of an alternative embodiment of a two stage LNA wherein the second stage comprises a cascode structure having two SOI transistors;

FIG. 7 depicts a circuit diagram of another embodiment of a two stage LNA, wherein both stages comprise a cascode structure;

FIG. 8 depicts a circuit diagram of another embodiment of a two stage LNA, wherein the first stage comprises a hybrid cascode structure;

FIG. 9 depicts the small signal plots of a LNA according to three different embodiments; and

FIG. 10 depicts the large signal plots of the same three embodiments.

### DETAILED DESCRIPTION

FIG. 1 shows a part of a telecommunications system 2 comprising an antenna 4 for transmitting and receiving electromagnetic signals, a switch 6 connected to the antenna for switching between transmission (Tx) and reception (Rx) modes, and a low noise amplifier (LNA) 8 for amplifying received signals from the antenna 4. The system further comprises a band shifter 10 for upshifting or downshifting signals, wherein the band shifter comprises a frequency synthesizer 12. The system 2 may be part of a node such as a base node in a 5G network for telecommunications, or a user equipment (UE) such as a mobile phone.

The present disclosure relates in particular to improvements in the LNA 8 of the system 2. The improvements provided by embodiments typically comprise one or more of high linearity, low signal to noise ratio (SNR), and low power consumption. Low power consumption may be particularly advantageous for UEs, which have a limited battery capacity.

To achieve one or more of these advantages, the LNA 8 comprises a semiconductor structure comprising a cascode structure. A cascode structure comprises two transistors, one acting as common emitter (or common source) and one as common base (or common gate). The cascode topology can offer higher gain and improved bandwidth by isolating input and output better than a common-emitter/source design. The semiconductor structure comprises a silicon on insulator (SOI) substrate comprising a buried oxide (BOX) layer between a silicon substrate (also referred to as the handling wafer) and an active silicon layer (also referred to as the device layer). Semiconductor devices such as transistors and diodes can be formed in the active silicon layer. At least one of the transistors of the cascode structure can be a bipolar transistor located in a so called bulk region of the substrate, where the BOX layer has been locally removed and replaced with silicon. The bulk region can provide increased heat dissipation, which can improve the performance of the SiGe transistor.

The LNA 8 comprises a number of passive devices, such as capacitors (C), inductors (L) and resistors (R), connected to the cascode structure. The passive devices are located on the SOI substrate over the BOX layer to benefit from the improved electrical isolation. The SOI substrate may be a high resistivity (HR) substrate. Increasing the resistance of the substrate layer can reduces cross talk between electronic components. For example, a silicon substrate having a resistivity of at least 3 kΩ-cm may be used.

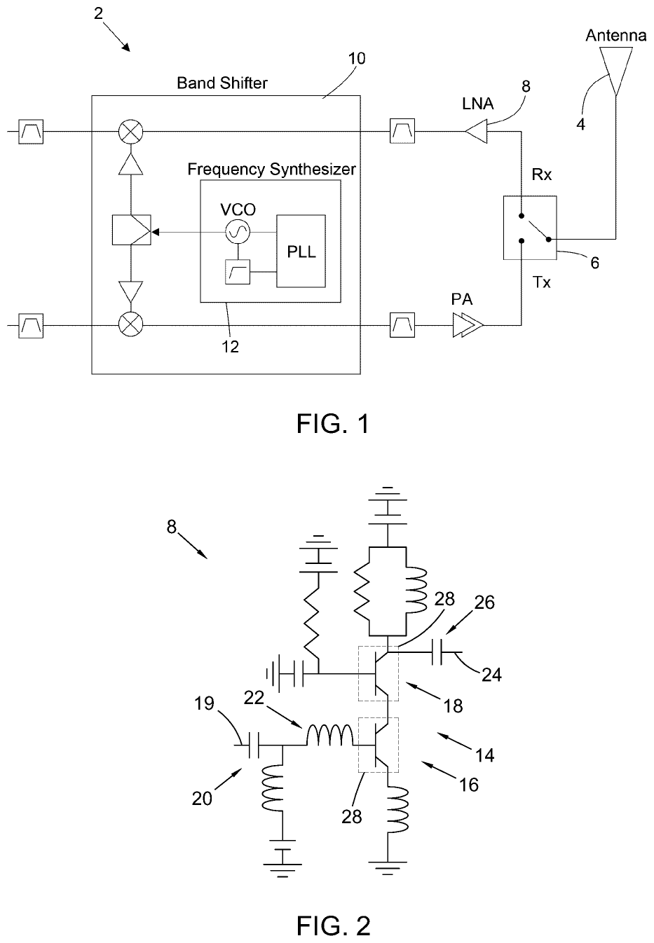

FIG. 2 shows a circuit diagram of an LNA 8 according to an embodiment. The same reference numerals have been used for the same or equivalent features in different figures for ease of understanding, and are not intended to limit the illustrated embodiments. The LNA 8 of FIG. 2 may be the LNA 8 of the system 2 illustrated in FIG. 1.

The LNA 8 comprises a cascode structure 14 comprising a first transistor 16 (the common emitter) and a second transistor 18 (the common base). The LNA 8 has an input 19 (Vin), feeding into the base of the first transistor 16 via a capacitor 20 and a inductor 22 used for input matching, for receiving a signal to be amplified (e.g. a signal from the antenna 4 of the system 2 as illustrated in FIG. 1 when in RX mode). The LNA 8 comprises an output 24 (Vout) from the collector of the second transistor 18 via a capacitor 26, for transmitting the amplified signal (e.g. to the band shifter 10 of the system 2 illustrated in FIG. 1). The first transistor 16 may be referred to as the input transistor and the second transistor 18 may be referred to as the output transistor of the cascode structure.

In this embodiment, both transistors 16, 18 of the cascode structure 14 are bipolar transistors (e.g. SiGe NPN transistors) formed in one or more bulk regions 28 in a SOI substrate. Forming both transistors 16, 18 of the cascode structure 14 in the same bulk region 28 (i.e. in the same opening of the BOX layer) can reduce losses of the interconnection between the transistors. Accordingly, the active devices (i.e. the transistors 16, 18) benefit from the bulk silicon (providing increased heat dissipation) while the passive devices (resistors, inductors 22 and capacitors 20, 26) benefit from the SOI substrate. The circuit can thereby benefit from the high quality SOI passives and the use of the bipolar transistor as input transistor 16 to reduce the noise. Advantages of the use of the bipolar transistor as cascode transistor may include high transition frequency (FT, e.g. around 300 GHz), low noise figure (NF) at microwave frequencies and low power consumption. The SOI substrate may be a high resistivity (HR) substrate. In other embodiments, only one of the transistors 16, 18 in the cascode structure is a bipolar transistor formed in a bulk region 28, while the other is a SOI transistor located over the BOX layer.

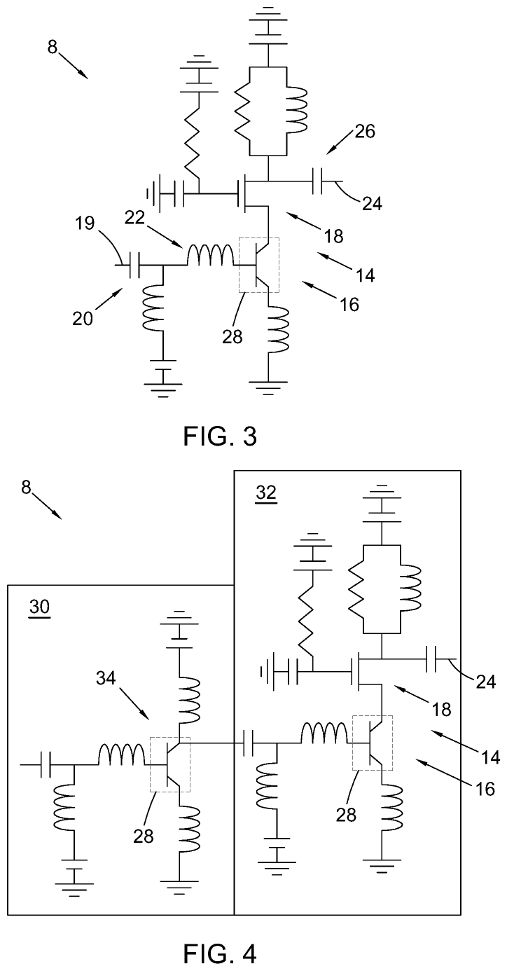

FIG. 3 shows a circuit diagram of a LNA 8 according to another embodiment. The LNA 8 comprises a cascode structure 14 comprising a first transistor 16 (common emitter), and a second transistor 18 (common gate). The circuit is similar to the one illustrated in FIG. 2, but the cascode structure comprises only one bipolar transistor 16, while the second transistor 18 is a SOI transistor located over the BOX layer of the SOI substrate and not in a bulk region 28 as the first transistor 16. Typically, the second transistor 18 is a complementary metal-oxide semiconductor (CMOS) transistor formed on the SOI substrate using one or more CMOS processes (the MOS transistor can be body-floating). This cascode structure 14 may be referred to as a hybrid cascode structure.

The LNA 8 has an input 19 connected to the base of the input transistor 16 via capacitor 20 and inductor 22, and an output 24 connected to the collector of the output transistor 18 via capacitor 26.

The common emitter transistor 16 used in this cascode is a bipolar SiGe transistor, which can provide a high FT (e.g. around 300 GHz), low power consumption (as the current flowing through the cascode is fixed by the SiGe transistor), lower minimum NF (NFmin) at microwave frequencies. The common gate transistor used is a 100 nm gate length SOI body floating NMOS transistor (for high frequency coverage), which can provide higher linearity compared to a bipolar transistor.

The noise figure (NF) for the LNA 8 can be given by

$${F}_{total} = {F}_{1} + \frac{{F}_{2} - 1}{{G}_{1}} + \frac{{F}_{3} - 1}{{G}_{1} {G}_{2}} + \frac{{F}_{4} - 1}{{G}_{1} {G}_{2} {G}_{3}} + ⋯ + \frac{{F}_{n} - 1}{{G}_{1} {G}_{2} … {G}_{n - 1}} , \qquad ( 1 )$$

where Fₙ is the noise factor of the n^{th} stage and Gₙ is the gain of the n^{th} stage. For example, for the cascode structure illustrated in FIG. 3 the common emitter transistor can be considered the first stage having noise factor F₁.

From equation 1 it is seen that the noise of the first stage dominates. The noise of the upper stage is reduced by the gain of the previous stages so that the dominant noise is the first stage one. Hence, it can be particularly advantageous to have a bipolar transistor such as the bipolar SiGe transistor as the common emitter of the cascode structure.

The IIP3 (Third order Input Intercept Point) of the LNA 8 can be given by

$${IIP}_{3} = \frac{1}{\frac{1}{{IIP}_{3 , 1}^{2}} + \frac{{G}_{1}^{2}}{{IIP}_{3 , 2}^{2}} + \frac{{G}_{1}^{2} \cdot {G}_{3}^{2}}{{IIP}_{3 , 3}^{2}} … + \frac{{G}_{1}^{2} \cdot {G}_{3}^{2} … \cdot {G}_{n - 1}^{2}}{{IIP}_{3 , n}^{2}}} , \qquad ( 2 )$$

wherein IIP_{3,n} is IIP3 of the n^{th} stage and Gn is the gain of the n^{th} stage.

From equation 2, the IIP3 of the last stage dominates the overall IIP3. Hence, it may be particularly advantageous to have a SOI transistor such as the SOI floating-body NMOS transistor as the common gate of the cascode structure.

The SiGe input transistor 16 determines the major part of the noise figure. The input SiGe transistor 16 also determines the current consumption, while the output transistor 18, which is SOI based, can provide a positive contribution to the linearity of the circuit. The hybrid cascode structure 14 can thereby provide both the positive performance of SiGe in terms of small signal performance and the linearity advantage of a SOI transistor in order to provide an LNA meeting 5G requirements.

FIG. 4 shows a circuit diagram of an LNA 8 according to an embodiment comprising two amplification stages 30, 32. The first stage 30 comprises a single common emitter configuration comprising a SiGe transistor 34 located in a bulk region 28 of the SOI substrate. The first stage 30 can thereby provide a lower NF compared to a cascode structure. The second stage 32 comprises a cascode structure 14, which may be the hybrid cascode structure 14 as illustrated in FIG. 3. Both stages 30, 32 comprise passive components formed on the SOI substrate over the BOX layer.

This single stage 30 determines the major part of the noise, while the second stage 32 contributes to the linearity of the system and increases the gain, without damaging the noise performances of the LNA.

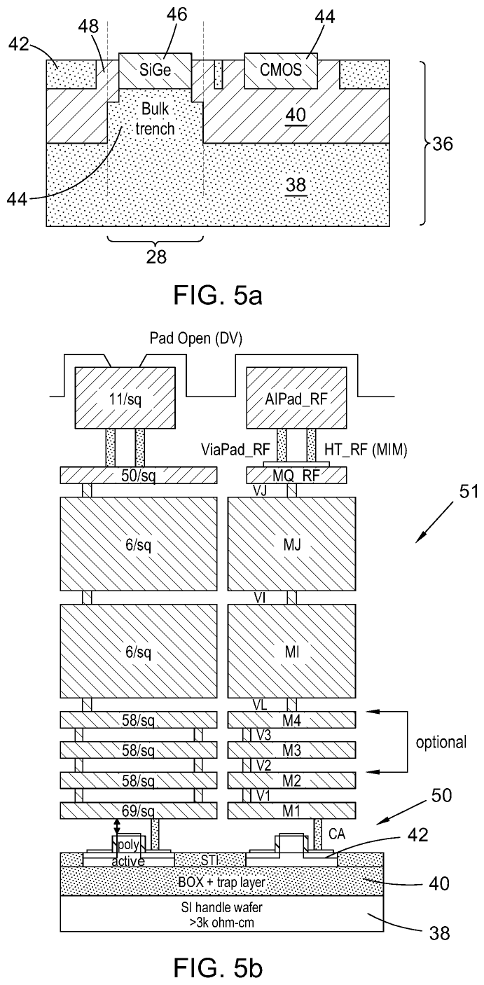

FIG. 5a shows a schematic cross section of a part of an LNA according to an embodiment. The LNA comprises a SOI substrate 36 comprising a silicon substrate 38 (the handling wafer), a BOX layer 40 and an active silicon layer 42. The LNA comprises a bulk region 28, within which the BOX layer 40 is removed. Typically, the bulk region 28 comprises epitaxial silicon 44 on the silicon layer 38. A SiGe transistor 46 is located in the bulk region 28. The transistor 46 may be the common emitter transistor of a cascode structure. The transistor 46 is laterally isolated by an isolation structure 48, such as STI (Shallow Trench Isolation). Because the BOX layer 40 has been removed in the bulk region 28, there is substantially no isolation between the SiGe transistor 46 and the silicon layer 38. The BOX layer 40 extends laterally on either side of the bulk region 28. In a region adjacent to the bulk region 28, a CMOS transistor 44 is located in the active silicon layer 42 over the BOX layer 40. The transistor 44 may be a SOI floating NMOS transistor of a cascode structure as illustrated in FIG. 3. The SiGe transistor 46 and CMOS transistor 44 may hence form a hybrid cascode structure, wherein the SiGe transistor 46 is the common emitter and the CMOS transistor 44 is the common gate.

FIG. 5b shows a schematic diagram of a part of a LNA according to an embodiment. In particular, metal layers 51 (M1 to M4, MI and MJ) on the SOI substrate connecting to transistors 50 over the BOX layer 40 are illustrated. Passive components, such as inductors, may be formed from or connected by the thick top metal layers MI and MJ. The low resistivity of the thick metal layers MI, MJ can improve the performance of the passive components and reduce noise of the LNA. For example, the thick metal layers allow for high quality factor inductors and low loss interconnections. The thick metal layers MI, MJ can have a thickness of about 3 μm. The metal layers 51 may typically be formed in the back end of line (BEOL) of a CMOS process. The “normal” metal layers (M1 to M4) have a thickness of about 0.35 μm. The silicon substrate 38 is a HR substrate having a resistivity greater than about 3 kΩ-cm.

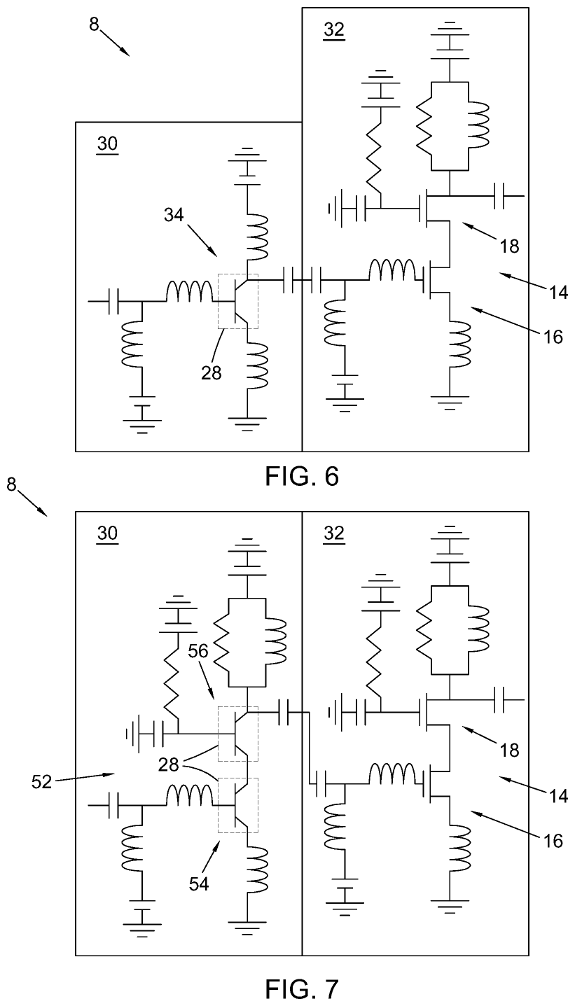

FIG. 6 shows a circuit diagram of an LNA 8 according to an alternative embodiment, which may be advantageous if linearity is a priority. The LNA comprises a first stage amplifying circuit 30 and a second stage amplifying circuit 32. The first stage 30 comprises a single common emitter comprising a bipolar transistor 34 (e.g. a SiGe transistor) located in a bulk region 28 for low noise, while the second stage 32 comprises a cascode structure 14 comprising two SOI transistors 16, 18 (e.g. CMOS transistors located over the BOX layer of the SOI substrate), for high linearity.

FIG. 7 shows the circuit of an LNA 8 according to an embodiment with two stages 30, 32 wherein each amplifying stage comprises a cascode structure 14, 52. The first amplifying stage 30 comprises a cascode structure comprising a first bipolar transistor 54 in a bulk region 28 as common emitter and a second bipolar transistor 56 in a bulk region 28 as common base. The second stage amplifying circuit 32 comprises a cascode structure 14 comprising a first SOI transistor 16 as common source and a second SOI transistor 18 as common gate.

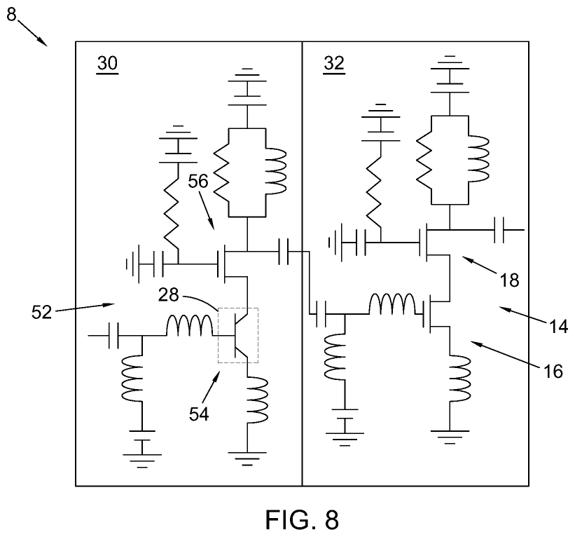

FIG. 8 shows the circuit of an LNA 8 according to an embodiment with two stages 30, 32 wherein each amplifying stage comprises a cascode structure 14, 52, but wherein the first stage 30 comprises a hybrid cascode structure 52 comprising a bipolar transistor 54 as common emitter and a SOI transistor 56 as common gate. The second stage 32 is similar to that of FIG. 7, comprising a cascode structure 14 with two SOI transistors.

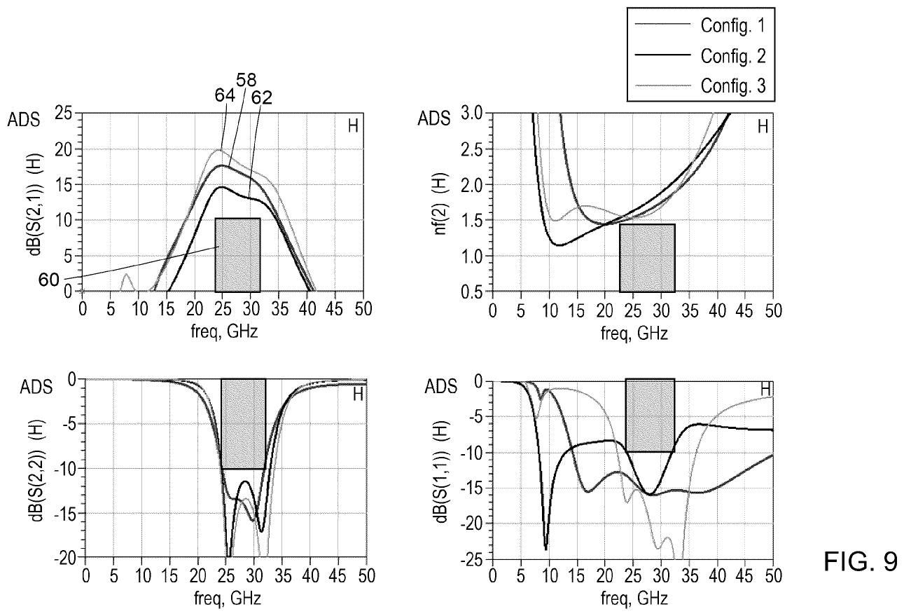

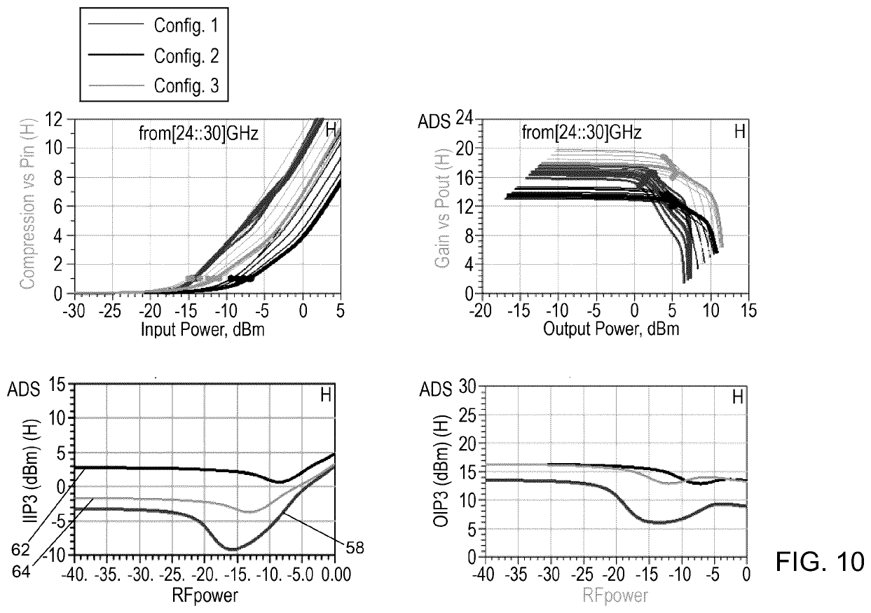

FIG. 9 shows four graphs illustrating the small signal plots (gain and noise) of three LNAs according to different configurations. The first configuration (config. 1, line 58), comprises a single amplifying stage with a cascode structure comprising SiGe transistors as both common emitter and common base (e.g. as illustrated in FIG. 2), it is seen that the band 60 of 28 GHz is covered with sufficient gain and the noise is around 1.64 dB at 28 GHz.

The second configuration (config. 2, line 62) comprises a SiGe transistor and a SOI transistor in a single cascode structure (e.g. as illustrated in FIG. 3). The 5G band is covered with less gain and slightly higher noise of about 1.78 dB at 28 GHz compared to the first configuration.

The third configuration (config. 3, line 64) comprises two amplifying stages (e.g. as illustrated in FIG. 4) with a single SiGe transistor in the first amplifying stage and a hybrid cascode structure in the second amplifying stage. The lost gain of config. 2 is compensated by the first stage. This configuration can give lower noise, between 25 and 30 GHz, due to the Friis formula.

FIG. 10 shows the large signal plots for the same three configurations. Config. 1 starts compression earlier than other configurations using SOI transistors. Configs. 2 and 3 have the same level of OP1 and OIP3. Config. 2 gives the best IP1 (Input Power at 1 dB of compression). The addition of one more stage (as in config. 3) increases the gain but reduces the IP1. The results indicate an advantage of using SOI transistors to improve linearity.

In general, embodiments disclosed herein provide a low noise amplifier (LNA) comprising a silicon on insulator (SOI) substrate comprising a buried oxide (BOX) layer, wherein said SOI substrate comprises a bulk region within which the buried oxide layer is removed, and a bipolar transistor located in said bulk region. The LNA further comprises a thick metal layer (e.g. the top metal) for connecting to the LNA. The bipolar transistor can be a SiGe (silicon germanium) transistor.

The SOI substrate is a high resistance (HR) SOI substrate comprising a silicon handling wafer having a resistivity greater than 3 kΩ-cm. For example, the silicon substrate may have a thickness in the range of 500 μm and 1000 μm. The HR SOI substrate may reduce parasitic capacitances. The LNA may further comprise a plurality of passive components (e.g. inductors, resistors and capacitors) formed on said SOI substrate over said BOX layer. The BOX layer may, for example, have a thickness in the range of 0.4 μm to 3 μm. The active silicon layer typically has a thickness of less than 1 μm, for example about 0.1 μm or 0.2 μm. Devices in the active silicon layer over the BOX layer, such as transistors, are typically separated by STI.

The passive components may be formed from and/or are connected by one thick metal layer (e.g. the top metal of a CMOS backend stack) or two at least partly overlapping thick metal layers. The thick metal layer or layers typically comprise copper. The thick metal layers may have a thickness greater than 1 μm. For example, the thick metal layers may have a thickness in the range of 2 μm to 4 μm, such as about 3 μm. The greater thickness can reduce resistance and improve the performance of at least some of the passive components. For example, inductors of the LNA may be formed by one or more coil turns in the thick metal layer(s). Typically, a plurality of metal layers are located on the SOI substrate wherein the thick metal layer or layers are located at the top (furthest away from the active silicon layer). Metal 1 is the first metal layer located closest to the active silicon and may be directly connected to the bipolar transistor. The first metal layer may have a thickness of less than 1 μm, for example a thickness of about 0.3 μm, which is significantly thinner than the tick metal layer(s). The plurality of metal layers may be separated by interdielectric layers (e.g. silicon oxide layers) and electrically connected by vias.

The LNA may comprise a cascode structure (also referred to as cascode topology) comprising said bipolar transistor being a common emitter of said cascode structure. The common base (gate) of the cascode structure can be a second bipolar transistor (e.g. a SiGe transistors) in a bulk region of the SOI substrate or a “normal” SOI transistor (e.g. CMOS transistor) formed in the active silicon layer over the BOX layer of the SOI substrate.

The LNA may comprise two amplifying stages, e.g. a first stage amplifying circuit and a second stage amplifying circuit, wherein said first stage amplifying circuit comprises said bipolar transistor and wherein said second stage amplifying circuit comprises a cascode structure. The cascode structure can comprises a first SOI transistor being a common source of said cascode structure and a second SOI transistor being a common gate of said cascode structure. In this embodiment, the second amplifying stage can comprise only SOI transistors (e.g. CMOS transistors), which may improve the linearity of the LNA. In another embodiment, said cascode structure can comprise a second bipolar transistor in a bulk region of said SOI substrate, wherein said second bipolar transistor is a common emitter of said cascode structure, and wherein the cascode structure comprises a SOI transistor being a common gate of said cascode structure. That is, the second amplifying stage comprises a hybrid cascode structure with one bipolar transistor in the bulk region and one SOI transistor. The first amplifying stage typically comprises a single common emitter (no cascode structure) being the bipolar transistor in the bulk region. Alternatively, said first stage amplifying circuit can comprise a second cascode structure comprising said bipolar transistor being a common emitter of said second cascode structure. Said second cascode structure can comprises a second bipolar transistor located in a bulk region of said SOI substrate, wherein said second bipolar transistor is a common base of said cascode structure. That is, both transistors of the cascode structure of the first amplifying stage are bipolar transistors (e.g. SiGe transistors) formed in a bulk region of the SOI substrate in this embodiment. In another embodiment, said second cascode structure comprises a SOI transistor being a common gate of said cascode structure (to form a hybrid cascode structure with the bipolar transistor).

Another embodiment provides an apparatus for telecommunications (e.g. a user equipment, UE, such as a mobile phone) comprising an LNA according to an embodiment disclosed herein, wherein the LNA is arranged in the apparatus to amplify a signal received by the apparatus.

While specific embodiments of the invention have been described above, it will be apparent to one skilled in the art that modifications may be made to the invention as described without departing from the scope of the claims set out below. Each feature disclosed or illustrated in the present specification may be incorporated in the invention, whether alone or in any appropriate combination with any other feature disclosed or illustrated herein.

What is claimed is:

1. A low noise amplifier, LNA, comprising:
a silicon on insulator, SOI, substrate comprising a buried oxide, BOX, layer, wherein said SOI substrate comprises a bulk region within which the buried oxide layer is removed, wherein said SOI substrate is a high resistance, HR, SOI substrate comprising a silicon handle wafer having a resistivity greater than 3 kΩ-cm;
a bipolar transistor located in said bulk region; and
a thick metal layer for connecting to the LNA.

2. The LNA according to claim 1, wherein said bipolar transistor is a SiGe transistor.

3. The LNA according to claim 1, further comprising a plurality of thin metal layers located between said thick metal layer and said SOI substrate.

4. The LNA according to claim 1, further comprising a second thick metal layer vertically displaced from the first thick metal layer so that the thick metal layers are at least partly overlapping.

5. The LNA according to claim 1, wherein the or each thick metal layer comprises copper.

6. The LNA according to claim 1, wherein the or each thick metal layer has a thickness greater than 1 μm.

7. The LNA according to claim 1, wherein the or each thick metal layer has a thickness in the range of 2 μm to 4 μm.

8. The LNA according to claim 1, wherein said LNA comprises a cascode structure, and wherein said bipolar transistor is a common emitter of said cascode structure.

9. The LNA according to claim 8, wherein said LNA comprises a second bipolar transistor which is arranged to form a common base of said cascode structure.

10. The LNA according to claim 8, further comprising a SOI transistor, wherein said cascode structure comprises said SOI transistor which is arranged to form a common gate of said cascode structure.

11. The LNA according to claim 10, wherein said SOI transistor is a complementary metal-oxide semiconductor (CMOS) transistor.

12. The LNA according to claim 1, and comprising a first stage amplifying circuit and a second stage amplifying circuit, wherein said first stage amplifying circuit comprises said bipolar transistor and wherein said second stage amplifying circuit comprises a cascode structure.

13. The LNA according to claim 12, wherein said cascode structure comprises a first SOI transistor being a common source of said cascode structure and a second SOI transistor being a common gate of said cascode structure.

14. The LNA according to claim 12, wherein said cascode structure comprises a second bipolar transistor in a bulk region of said SOI substrate, wherein said second bipolar transistor is a common emitter of said cascode structure, and a SOI transistor is a common gate of said cascode structure.

15. The LNA according to claim 12, wherein said first stage amplifying circuit comprises a second cascode structure comprising said bipolar transistor being a common emitter of said second cascode structure.

16. The LNA according to claim 15, wherein said second cascode structure comprises a second bipolar transistor located in a bulk region of said SOI substrate, wherein said second bipolar transistor is a common base of said cascode structure.

17. The LNA according to claim 15, wherein said second cascode structure comprises a SOI transistor being a common gate of said cascode structure.

18. An apparatus for telecommunications comprising the LNA according to claim 1, wherein the LNA is arranged in the apparatus to amplify a signal received by the apparatus.
